(19) United States
(12) Patent Application Publication
(10) Pub. No.: US 2022/0365038 A1
(43) Pub. Date: Nov. 17, 2022

(54) BATTERY IN-SITU TEST SYSTEM

(71) Applicants: JILIN UNIVERSITY, Changchun City (CN); WEIHAI INSTITUTE FOR BIONICS-JILIN UNIVERSITY, Weihai City (CN)

(72) Inventors: Zhichao Ma, Changchun City (CN); Siguo Yang, Changchun City (CN); Changyi Liu, Changchun City (CN); Hongwei Zhao, Changchun City (CN); Luquan Ren, Changchun City (CN); Shenghui Wang, Changchun City (CN); Zixin Guo, Changchun City (CN); Jiong Liu, Changchun City (CN); Hua Zhou, Changchun City (CN); Haibin Li, Changchun City (CN); Lei Liu, Changchun City (CN)

(21) Appl. No.: 17/358,661

(22) Filed: Jun. 25, 2021

(30) Foreign Application Priority Data
May 11, 2021 (CN) 202110511698.3

(51) Int. Cl. G01N 29/265; G01N 29/06; G01K 7/18; G01J 5/08; H02J 7/00; H01M 10/42; H04N 5/33

(52) U.S. Cl. CPC G01N 29/265; G01N 29/0654; G01K 7/18; G01J 5/0806; H02J 7/0047; H01M 10/4285; H04N 5/33; G01J 2005/0077

(57) ABSTRACT

Disclosed is a battery in-situ test system. The battery in-situ test system comprises a charging and discharging module, an environment module and a mechanical loading module, wherein a to-be-tested battery is electrically connected with the charging and discharging module, the environment module comprises a temperature control box, the to-be-tested battery, an optical imaging module, an infrared thermal imaging module and an ultrasonic scanning imaging module are arranged in the temperature control box. The test environment is simulated through the environment module, and the optical imaging module is used for observing the microscopic deformation or damage of the surface of the to-be-tested battery; the infrared thermal imaging module is used for identifying the temperature distortion point of the to-be-tested battery and observing the thermal runaway process of the to-be-tested battery; and the ultrasonic scanning imaging module is used for monitoring the damage, lithium separation and charge state of the to-be-tested battery.

### CROSS REFERENCE TO RELATED APPLICATION(S)

This patent application claims the benefit and priority of Chinese Patent Application No. 202110511698.3, filed on May 11, 2021, the disclosure of which is incorporated by reference herein in its entirety as part of the present application.

### TECHNICAL FIELD

The present disclosure relates to the technical field of precise instruments, in particular to a battery in-situ test system.

### BACKGROUND ART

With the development of new energy vehicles, a high-specific-energy and high-working-voltage battery represented by a new-generation lithium ion technology has become a main power source of electric vehicles at present and a research hot spot of future vehicle power batteries. However, the electrochemical cycle performance and safety of the lithium ion battery in cold environments are still weak links of the technology. Deposition and embedding phenomena caused by cyclic charge-discharge behaviors in low-temperature environments accelerate battery aging, and a resulting dendritic crystal phenomenon easily causes battery short circuit and even causes property loss and malignant accidents, so that the phenomena are technical problems urgently required to be solved of the lithium ion battery and also limit development of new energy vehicles in cold areas. In-situ (In Situ) testing refers to a technology for monitoring the organization structure evolution of materials under complex environment and load effects in real time besides obtaining the inherent mechanical property parameters of the materials in the mechanical property testing process of various solid materials. A battery measuring instrument in the prior art is single in function, can only carry out qualification inspection on one performance, and cannot simulate the real service condition of the lithium ion battery.

Therefore, in order to ensure the service life, the specific energy and the safety of the lithium ion battery in the service process, especially in cold environments, research and development of an instrument which can simulate the complex service condition of the lithium ion battery and can perform multi-mode-multi-angle testing are very important for popularization and application of the lithium ion battery.

### SUMMARY

The present disclosure aims to provide a battery in-situ test system to solve the problems existing in the prior art, and can monitor the surface deformation, temperature distribution and internal damage of a to-be-tested battery.

To achieve the purpose, the present disclosure provides the following scheme:

A battery in-situ test system provided by the present disclosure comprises a charging and discharging module, an environment module and a mechanical loading module, a to-be-tested battery is electrically connected with the charging and discharging module, the environment module comprises a temperature control box, the to-be-tested battery, an optical imaging module, an infrared thermal imaging module and an ultrasonic scanning imaging module are arranged in the temperature control box, and the mechanical loading module is used for loading the to-be-tested battery.

Preferably, the mechanical loading module comprises a loading driving mechanism, a clamp and a first pricking needle, the clamp is located in the environment module and used for clamping the to-be-tested battery, the first pricking needle is arranged below the to-be-tested battery, a pricking needle extruding structure is arranged above the to-be-tested battery, and the loading driving mechanism drives the pricking needle extruding structure to do linear movement.

Preferably, the battery in-situ test system further comprises a rack, the rack comprises a plurality of stand columns and a cross beam, the loading driving mechanism drives the cross beam to slide along the stand columns, the environment module is fixed to a workbench of the rack, the pricking needle extruding structure comprises a connecting flange and a guide rod, the connecting flange is arranged on the cross beam, a pressure sensor is arranged between the connecting flange and the guide rod, and the lower end of the guide rod is detachably connected with a pressing plate or a second pricking needle.

Preferably, the clamp is arranged on a vibration isolation table, the first pricking needle penetrates through a through groove in the vibration isolation table, and the center line of the pricking needle extruding structure coincides with the center line of the first pricking needle.

Preferably, the environment module further comprises a temperature control structure, the temperature control structure comprises a plurality of refrigeration structures and a plurality of temperature sensors, the refrigeration structures are arranged on the outer side of the clamp, and the temperature sensors are arranged on the inner wall of the clamp, the inner walls of the refrigeration structures, the surface of the to-be-tested battery and electrodes of the to-be-tested battery.

Preferably, each refrigeration structure comprises a cooling fin and a plurality of refrigeration sheets, the cooling fins are arranged on the outer side of the clamp, the refrigeration sheets are arranged between the clamp and the cooling fins, and the sizes of the refrigeration sheets in each refrigeration structure are gradually increased from the clamp to the cooling fins.

Preferably, the optical imaging module comprises a first bottom plate, a first driving mechanism, a first support and an optical lens, the first bottom plate is fixed to the inner wall of the temperature control box, the first driving mechanism is fixed to the first bottom plate, the first driving mechanism drives the first support to be slidably connected with the first bottom plate, and the optical lens can be slidably connected with the first support and locked with the first support through a hand wheel.

Preferably, the infrared thermal imaging module comprises a second bottom plate, a second driving mechanism, a third driving mechanism, a transmission mechanism and an infrared lens, the second bottom plate is fixed to the inner wall of the temperature control box, the second driving mechanism drives the infrared lens to rotate, the third driving mechanism drives a second support to rotate through the transmission mechanism, and the infrared lens is rotationally connected with the second support.

Preferably, the transmission mechanism comprises a first connecting block, a first connecting rod, a second connecting block and a second connecting rod which are hinged in sequence, the first connecting block, the first connecting rod, the second connecting block and the second connecting rod form a parallelogram structure, the first connecting block is in transmission connection with the power output end of the third driving mechanism, and the second connecting block is in transmission connection with the second support.

Preferably, the ultrasonic scanning imaging module comprises a three-axis movement mechanism and an ultrasonic probe, the three-axis movement mechanism comprises an X-direction movement mechanism, a Y-direction movement mechanism and a Z-direction movement mechanism, the Y-direction movement mechanism is respectively slidably connected with the X-direction movement mechanism and the Z-direction movement mechanism, the ultrasonic probe is arranged on the Z-direction movement mechanism, the ultrasonic probe comprises a transmitting probe and a receiving probe, and when the ultrasonic scanning imaging module works, the transmitting probe and the receiving probe are located on the two sides of the to-be-tested battery.

Compared with the prior art, the present disclosure has the following technical effects:

The test environment is simulated through the environment module, the to-be-tested battery is loaded through the mechanical loading module, and the optical imaging module is used for observing the microscopic deformation or damage of the surface of the to-be-tested battery; the infrared thermal imaging module is used for identifying the temperature distortion point of the to-be-tested battery and observing the thermal runaway process of the to-be-tested battery; and the ultrasonic scanning imaging module is used for monitoring the damage, lithium separation and charge state of the to-be-tested battery. The present disclosure provides instrument support for revealing the performance degradation mechanism and the service life change rule of the battery under the force-low temperature-electrochemical coupling multiple external fields.

The present disclosure aims to solve the problems of internal short circuit, thermal runaway, even fire, explosion and the like caused by mechanical abuse, thermal abuse and electric abuse of the lithium ion battery under cold conditions, especially the problems of reduced capacity and shortened service life of the lithium ion battery, obvious lithium separation and unbalanced lithium de-intercalation in low-temperature environments. Through fusion of the mechanical loading module, a temperature real-time regulation technology, a multi-spectral-acoustic spectrum characterization technology and a charge-discharge performance test technology, the complex loads such as extrusion, collision and alternating stress as well as the use conditions such as over-charge/over-discharge of the lithium battery in the cold environments are simulated, force-low temperature-electrochemical coupling failure behaviors are tested, the correlation between the microstructure evolution behavior and service performance degradation of the battery material is obtained in real time, and the key problems such as multi-spectrum and multi-mode in-situ testing of dendritic crystal evolution behaviors and the threshold judgment of micro-scale internal short circuit are solved.

### BRIEF DESCRIPTION OF THE DRAWINGS

To more clearly illustrate the embodiment of the present disclosure or the technical scheme in the prior art, the following briefly introduces the attached figures to be used in the embodiment. Apparently, the attached figures in the following description show merely some embodiments of the present disclosure, and those skilled in the art may still derive other drawings from these attached figures without creative efforts.

FIG. 1 is an axonometric drawing of a battery in-situ test system in the present disclosure;

FIG. 2 is a front view of the battery in-situ test system in the present disclosure;

FIG. 3 is a schematic diagram of a mechanical loading module in the present disclosure;

FIG. 4 is a structural schematic diagram of a pricking needle extruding structure in the present disclosure;

FIG. 5 is a structural schematic diagram of a temperature control structure in the present disclosure;

FIG. 6 is an axonometric drawing of an optical imaging module in the present disclosure;

FIG. 7 is a front view of the optical imaging module in the present disclosure;

FIG. 8 is an axonometric drawing (without a second bottom plate) of an infrared thermal imaging module in the present disclosure;

FIG. 9 is a side view of the infrared thermal imaging module in the present disclosure;

FIG. 10 is an upward view of the infrared thermal imaging module in the present disclosure;

FIG. 11 is an axonometric drawing of an ultrasonic scanning imaging module in the present disclosure; and

FIG. 12 is a front view of the ultrasonic scanning imaging module in the present disclosure.

Reference signs in drawings: 100, battery in-situ test system; 1, charging and discharging module; 2, environment module; 3, mechanical loading module; 4, temperature control box; 5, to-be-tested battery; 6, optical imaging module; 7, infrared thermal imaging module; 8, ultrasonic scanning imaging module; 9, clamp; 10, first pricking needle; 11, pricking needle extruding structure; 12, rack; 13, stand column; 14, cross beam; 15, workbench; 16, flange; 17, guide rod; 18, pressure sensor; 19, pressing plate; 20, second pricking needle; 21, vibration isolation table; 22, temperature control structure; 23, refrigeration structure; 24, temperature sensor; 25, cooling fin; 26, refrigeration sheet; 27, first bottom plate; 28, first driving mechanism; 29, first support; 30, optical lens; 31, hand wheel; 32, second bottom plate; 33, second driving mechanism; 34, third driving mechanism; 35, transmission structure; 36, infrared lens; 37, second support; 38, first connecting block; 39, first connecting rod; 40, second connecting block; 41, second connecting rod; 42, three-axis movement mechanism; 43, ultrasonic probe; 44, X-direction movement mechanism; 45, Y-direction movement mechanism; 46, Z-direction movement mechanism; 47, transmitting probe; 48, receiving probe; 49, photoelectric encoder; 50, first motor; 51, guide rail; 52, ball screw pair; 53, socket head cap screw; 54, pin; 55, partition plate; 56, rotating shaft; 57, second motor; 58, ball screw assembly; and 59, third support.

### DETAILED DESCRIPTION OF THE EMBODIMENTS

The following clearly and completely describes the technical scheme in the embodiments of the present disclosure with reference to the attached figures in the embodiments of the present disclosure. Apparently, the described embodiments are merely a part rather than all of the embodiments of the present disclosure. Based on the embodiment in the present disclosure, all other embodiments obtained by the ordinary technical staff in the art under the premise of without contributing creative labor belong to the scope protected by the present disclosure.

The present disclosure aims to provide a battery in-situ test system to solve the problems existing in the prior art, and can monitor the surface deformation, temperature distribution and internal damage of a to-be-tested battery.

To make the foregoing objective, features and advantages of the present disclosure clearer and more comprehensible, the present disclosure is further described in detail below with reference to the attached figures and specific embodiments.

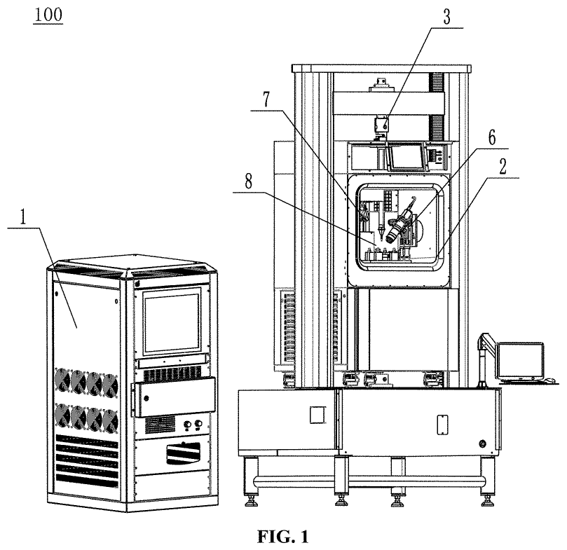

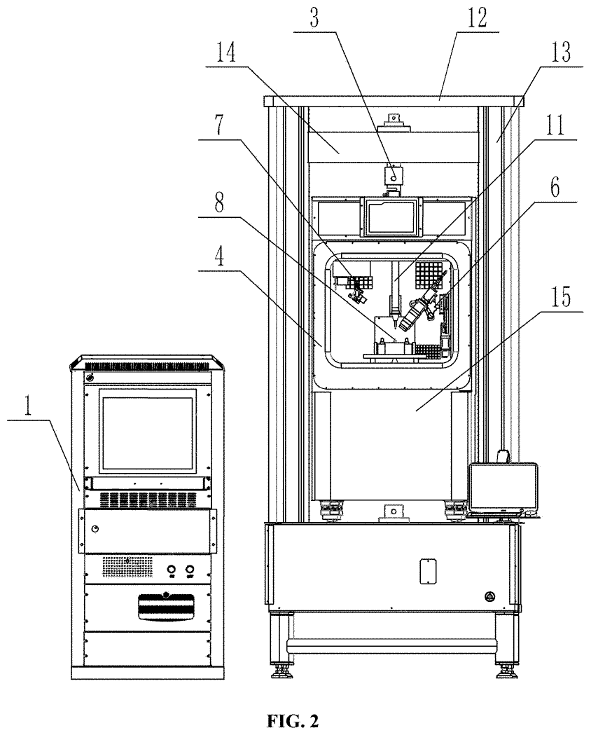

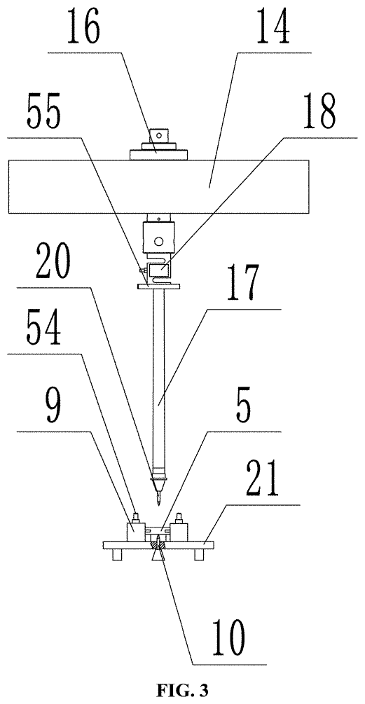

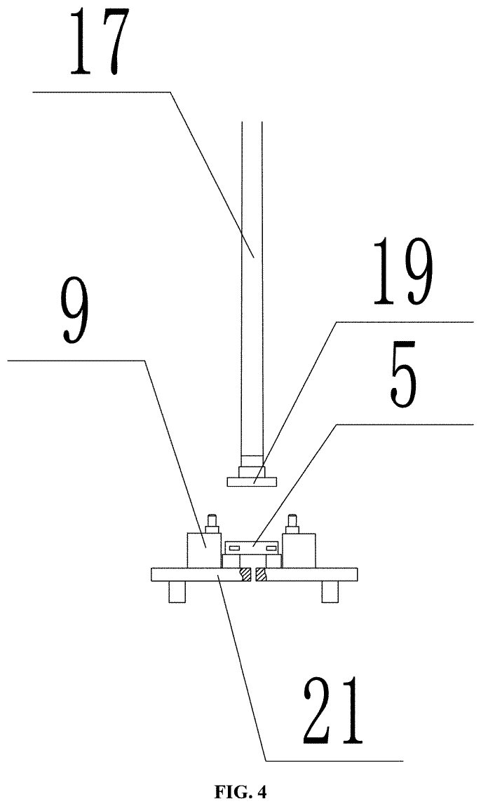

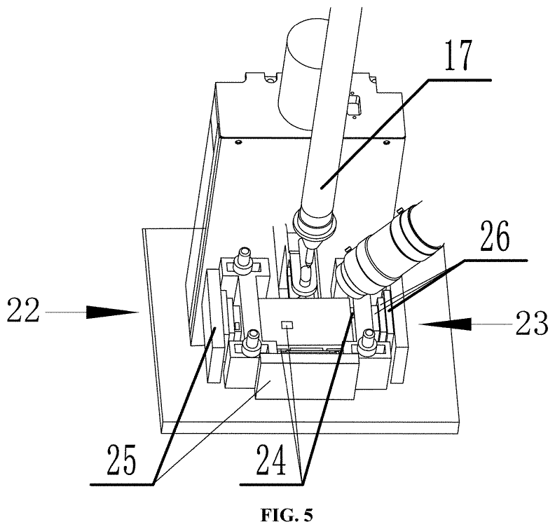

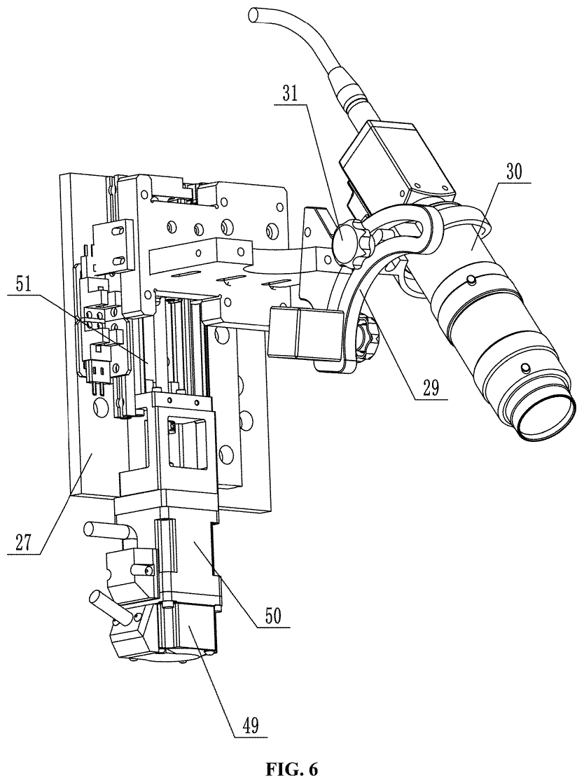

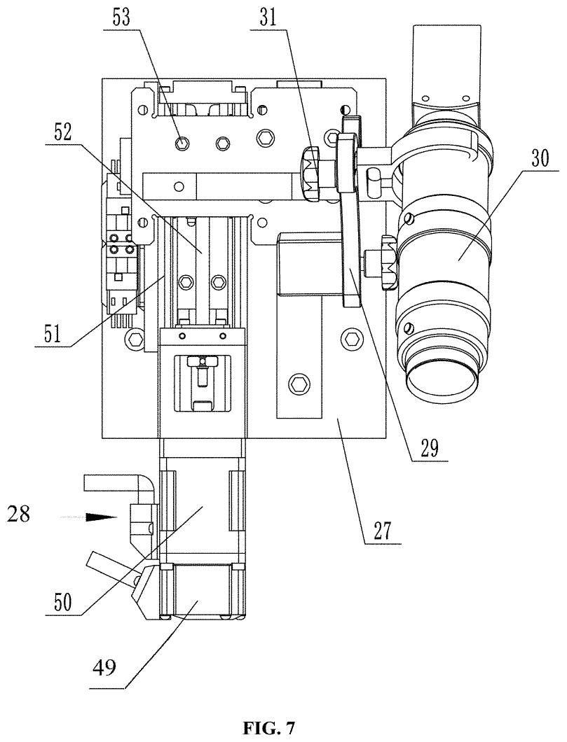

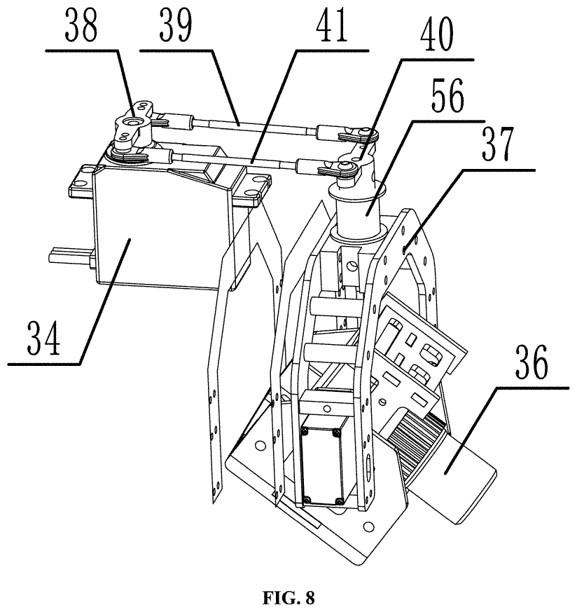

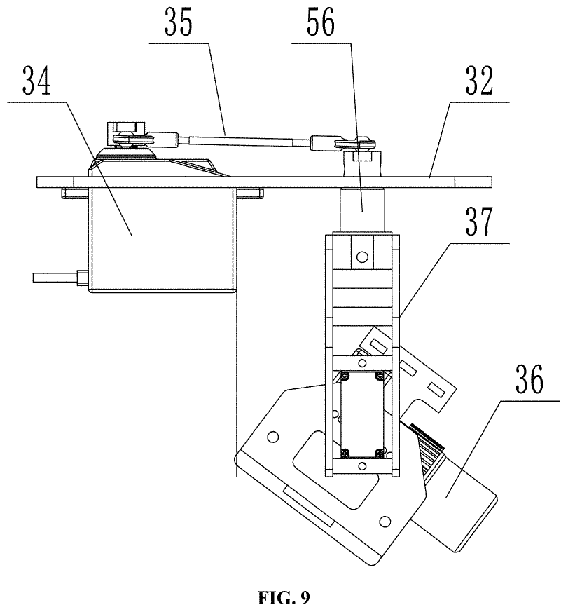

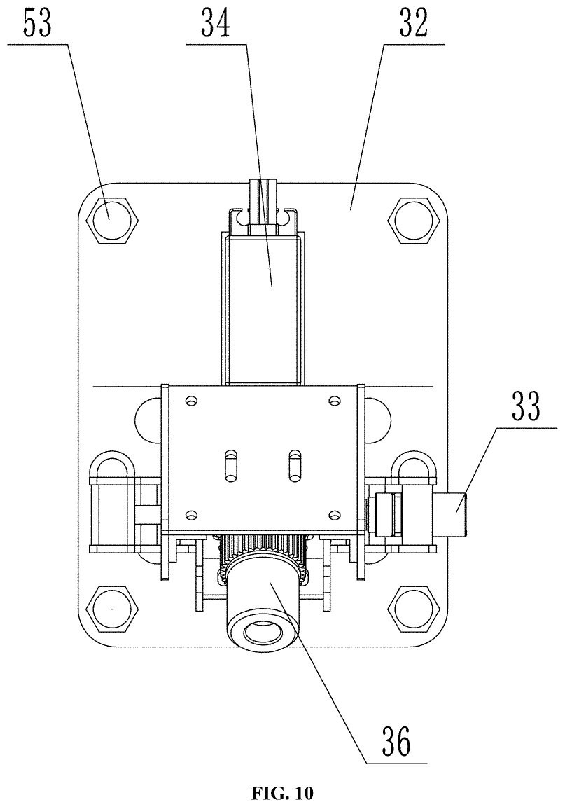

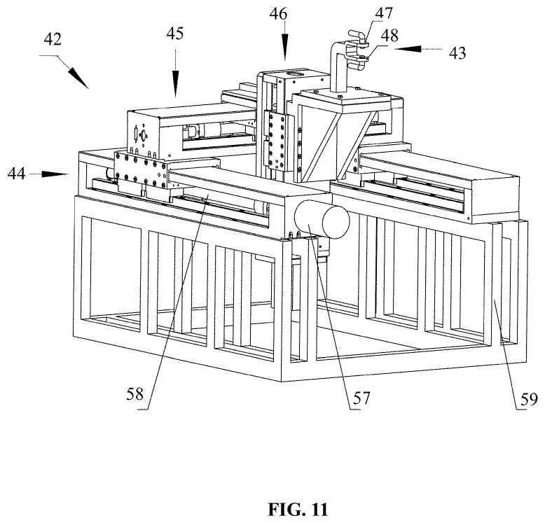

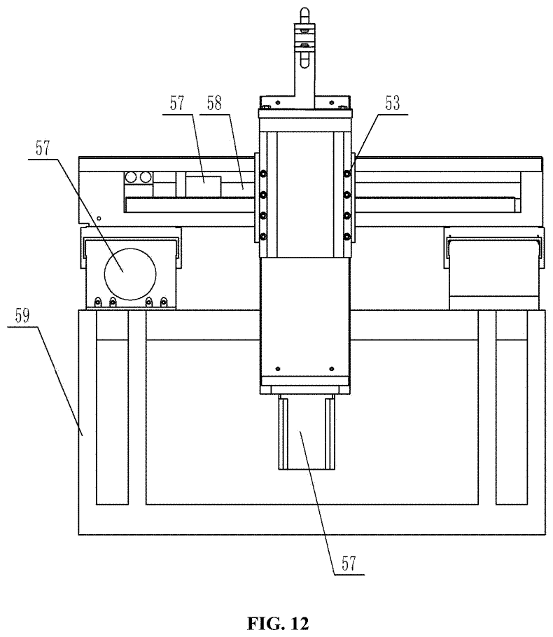

As shown in FIG. 1 to FIG. 12, the embodiment provides a battery in-situ test system 100, the overall dimensions of the system are 1300 mm×796 mm×1620 mm, and the dimensions of the to-be-tested battery 5 are 592 mm×657 mm×1081 mm. The battery in-situ test system comprises a charging and discharging module 1, an environment module 2 and a mechanical loading module 3, the to-be-tested battery 5 is electrically connected with the charging and discharging module 1, a lithium battery cell is selected and used as the to-be-tested battery 5, the mechanical loading module 3 is used for loading the to-be-tested battery 5, the environment module 2 comprises a temperature control box 4, the temperature control box 4 is of a semi-closed structure and can create a constant temperature environment for the to-be-tested battery 5, and the to-be-tested battery 5, an optical imaging module 6, an infrared thermal imaging module 7 and an ultrasonic scanning imaging module 8 are arranged in the temperature control box 4.

In the embodiment, the charging and discharging module 1 is full-automatic programmable charging and discharging equipment of the to-be-tested battery 5, the to-be-tested battery 5 is subjected to an over-charge/over-discharge test under the constant-current, constant-voltage, constant-resistance and constant-power modes through the charging and discharging module 1, the charging and discharging test can be carried out when the to-be-tested battery 5 is loaded, the performance change of the to-be-tested battery 5 under the actual working condition is simulated, the capacity, the direct-current internal resistance, the cycle life, the over-discharge and over-discharge rate bearing capacity and the state-of-charge holding capacity parameters of the to-be-tested battery 5 are monitored in real time, and dynamic conditions are provided for the performance test of the to-be-tested battery 5.

In the embodiment, the mechanical loading module 3 comprises a loading driving mechanism, a clamp 9 and a first pricking needle 10, the clamp 9 is located in the environment module 2 and used for clamping the to-be-tested battery 5, the first pricking needle 10 is arranged below the to-be-tested battery 5, a pricking needle extruding structure 11 is arranged above the to-be-tested battery 5, and the loading driving mechanism drives the pricking needle extruding structure 11 to do linear movement.

In the embodiment, the loading driving mechanism comprises a direct-current servo motor, a worm and gear reducing mechanism, a ball screw mechanism and a photoelectric encoder 49, the direct-current servo motor drives the ball screw mechanism through the worm and gear reducing mechanism, the ball screw mechanism transmits power to the cross beam 14 so as to mechanically load the to-be-tested battery 5, the photoelectric encoder 49 can feed the position of the pricking needle extending structure 11 back to a controller to realize various loading modes such as dynamic and static extrusion/pricking needle load and alternating load, and the working condition that the to-be-tested battery 5 bears extrusion, impact and vibration load in a large-speed range is simulated.

In the embodiment, the battery in-situ test system 100 further comprises a rack 12, the rack 12 comprises a plurality of stand columns 13 and a cross beam 14, the loading driving mechanism drives the cross beam 14 to slide along the stand columns 13, the environment module 2 is fixed to a workbench 15 of the rack 12, the pricking needle extruding structure 11 comprises a connecting flange 16 and a guide rod 17, the connecting flange 16 is arranged on the cross beam 14, a pressure sensor 18 is arranged between the connecting flange 16 and the guide rod 17, the pressure sensor 18 is connected with the guide rod 17 through a partition plate 55, the lower end of the guide rod 17 is detachably connected with a pressing plate 19 or a second pricking needle 20, and the lower end of the guide rod 17 is in threaded connection with the pressing plate 19 or the second pricking needle 20. By arranging the second pricking needle 20, the opposite-vertex pricking test of the to-be-tested battery 5 can be realized, and the second pricking needle 20 is replaced by the pressing plate 19 so that the to-be-tested battery 5 can be subjected to an extrusion test.

In the embodiment, the clamp 9 is arranged on a vibration isolation table 21, the first pricking needle 10 penetrates through a through groove in the vibration isolation table 21, the needle point of the first pricking needle 10 makes contact with the lower surface of the to-be-tested battery 5, the center line of the pricking needle extruding structure 11 coincides with the center line of the first pricking needle 10, and two lug bosses are arranged on the two sides of the through groove for supporting the to-be-tested battery 5.

In the embodiment, the first pricking needle 10 and the second pricking needle 20 are both carbon fiber composite pricking needles with excellent performances such as high strength, high modulus, high temperature resistance, friction resistance and excellent corrosion resistance, and the first pricking needle 10 and the second pricking needle 20 are both provided with metal coatings, so that the defect of insufficient conductivity of the carbon fiber composite material can be overcome while the excellent performances of the carbon fiber composite material are kept, and the problem that a traditional metal pricking needle is difficult to penetrate through the metal shell of the battery cell is solved. The opposite-vertex pricking loading method of the first pricking needle 10 and the second pricking needle 20 is characterized in that the first pricking needle 10 and the second pricking needle 20 carry out pricking loading on the to-be-tested battery 5 at the same time on the same straight line, battery stress release in a traditional single pricking test can be reduced while short circuit in the battery is simulated, and then more extreme working conditions are manufactured.

In the embodiment, the environment module 2 further comprises a temperature control structure 22, the temperature control structure 22 comprises a plurality of refrigeration structures 23 and a plurality of temperature sensors 24, the refrigeration structures 23 are arranged on the outer side of the clamp 9, the number of the refrigeration structures 23 in the embodiment is three, the three refrigeration structures 23 are respectively arranged on the outer side of the clamp 9 around three surfaces of the to-be-tested battery 5, the other surface of the to-be-tested battery 5 is provided with the ultrasonic scanning imaging module 8, the temperature sensors 24 are arranged on the inner wall of the clamp 9, the inner walls of the refrigeration structures 23, the surface of the to-be-tested battery 5 and electrodes of the to-be-tested battery 5 to realize real-time monitoring for local environment of the to-be-tested battery 5. The temperature sensors 24 are chip platinum thermal resistance sensors.

In the embodiment, each refrigeration structure 23 comprises a cooling fin 25 and a plurality of refrigeration sheets 26, the cooling fins 25 are made of a metal material, the cooling fins 25 are arranged on the outer side of the clamp 9, the refrigeration sheets 26 are arranged between the clamp 9 and the cooling fins 25, the sizes of the refrigeration sheets 26 in each refrigeration structure 23 are gradually increased from the clamp 9 to the cooling fins 25, the number of the refrigeration sheets 26 in each refrigeration structure 23 in the embodiment is three, the refrigeration sheet 26 with the minimum size is bonded with the clamp 9 through super glue, and the refrigeration sheet 26 with the maximum size is fixed with the cooling fins 25 through screws, so that the cooling area is the largest, and the refrigeration effect is guaranteed. The refrigeration structures 23 are bonded on the clamp 9 to realize local low temperature of the to-be-tested battery 5, and the temperature sensors 24 can accurately regulate and control the local temperature.

In the embodiment, the environment module 2 can realize the construction of a local low-temperature environment of minus 40° C., and meanwhile, the infrared thermal imaging technology of the infrared thermal imaging module 7 is combined to monitor the global temperature distribution of the to-be-tested battery 5 in real time, so that the rapid change of the temperature rise rate of the battery in the process of inducing thermal runaway by internal short circuit can be helped to be evaluated, and critical temperature conditions for separating active substances and gas in the battery out of a safety valve when thermal runaway is triggered are determined.

In the embodiment, when the environment module 2 is loaded, the temperature control box 4 is started, and the refrigeration structures 23 and the temperature sensors 24 are powered on, so that the construction and monitoring of the adjustable constant low-temperature environment can be realized.

In the embodiment, the optical imaging module 6 comprises a first bottom plate 27, a first driving mechanism 28, a first support 29 and an optical lens 30, the first bottom plate 27 is fixed to the inner wall of the temperature control box 4, the first driving mechanism 28 is fixed to the first bottom plate 27, the first driving mechanism 28 drives the first support 29 to be slidably connected with the first bottom plate 27, and the optical lens 30 can be slidably connected with the first support 29 and locked with the first support 29 through a hand wheel 31. The optical lens 30 is a high-depth-of-field continuous zoom optical microscope lens. The first driving mechanism 28 comprises a first motor 50, the first motor 50 drives a ball screw pair 52 to rotate, the optical lens 30 does linear movement along a guide rail 51, the hand wheel 31 can control the position of the optical lens 30 on the first support 29 to adjust the initial monitoring angle, and through multi-degree-of-freedom movement and zooming of the optical lens 30, accurate imaging of different parts and different depths of the to-be-tested battery 5 can be realized. The first motor 50, together with the photoelectric encoder 49, is connected with the ball screw pair 52 through a coupler, a ball screw of the ball screw pair 52 is rotationally connected with the first bottom plate 27, the guide rail 51 is fixed to the first bottom plate 27, and a nut of the ball screw pair 52 is fixedly connected with the first support 29. The first motor 50 drives the ball screw pair 52 to move, and the ball screw pair 52 drives the first support 29 and the optical lens 30 to move.

In the embodiment, the infrared thermal imaging module 7 comprises a second bottom plate, a second driving mechanism 33, a third driving mechanism 34, a transmission mechanism 35 and an infrared lens 36, the infrared lens 36 is an infrared thermal imaging lens, the second driving mechanism 33 is a direct-current servo motor, the third driving mechanism 34 is a torsional servo motor, the second bottom plate 32 is fixed to the inner wall of the temperature control box 4, the second driving mechanism 33 drives the infrared lens 36 to rotate around the axis of the power output end of the second driving mechanism 33, the third driving mechanism 34 drives a second support 37 to rotate through the transmission mechanism 35, and the infrared lens 36 is rotationally connected with the second support 37.

In the embodiment, the transmission mechanism 35 comprises a first connecting block 38, a first connecting rod 39, a second connecting block 40 and a second connecting rod 41 which are hinged in sequence, the first connecting block 38, the first connecting rod 39, the second connecting block 40 and the second connecting rod 41 form a parallelogram structure, the first connecting block 38 is in transmission connection with the power output end of the third driving mechanism 34, the second connecting block 40 is in transmission connection with the second support 37 through a rotating shaft 56, the rotating shaft 56 is rotationally connected with the second bottom plate 32, the third driving mechanism 34 drives the second support 37 to rotate around the axis of the rotating shaft 56, and the axis of the power output end of the second driving mechanism 33 is vertical to the axis of the rotating shaft 56. Through the two rotation modes, two rotation degrees of freedom of the infrared lens 36 can be realized, and real-time heat tracing and distortion point temperature identification can be carried out on the to-be-tested battery 5.

In the embodiment, the ultrasonic scanning imaging module 8 comprises a three-axis movement mechanism 42 and an ultrasonic probe 43, the three-axis movement mechanism 42 is arranged on a third support 59, the three-axis movement mechanism 42 comprises an X-direction movement mechanism 44, a Y-direction movement mechanism 45 and a Z-direction movement mechanism 46, the Y-direction movement mechanism 45 is respectively slidably connected with the X-direction movement mechanism 44 and the Z-direction movement mechanism 46, and the ultrasonic probe 43 is arranged on the Z-direction movement mechanism 46. Each of the X-direction movement mechanism 44, the Y-direction movement mechanism 45 and the Z-direction movement mechanism 46 comprises a second motor 57, a ball screw assembly 58 and a sliding block, the second motor 57 of the X-direction movement mechanism 44 drives the ball screw assembly 58 of the X-direction movement mechanism 44 to rotate, and the sliding block of the X-direction movement mechanism 44 drives the Y-direction movement mechanism 45 to slide; the second motor 57 of the Y-direction movement mechanism 45 drives the ball screw assembly 58 of the Y-direction movement mechanism 45 to rotate, and the sliding block of the Y-direction movement mechanism 45 drives the Z-direction movement mechanism 46 to slide; and the second motor 57 of the Z-direction movement mechanism 46 drives the ball screw assembly 58 of the Z-direction movement mechanism 46 to rotate, and the sliding block of the Z-direction movement mechanism 46 drives the ultrasonic probe 43 to slide.

In the embodiment, the ultrasonic probe 43 comprises a transmitting probe 47 and a receiving probe 48, the transmitting probe 47 and the receiving probe 48 are respectively arranged at the back of the to-be-tested battery 5 through a square groove in the vibration isolation table 21, and when the ultrasonic scanning imaging module 8 works, the transmitting probe 47 and the receiving probe 48 are located on the two sides of the to-be-tested battery 5. After the loading of mechanical loading module 3 is finished, the X-direction movement mechanism 44 and the Y-direction movement mechanism 45 drive the ultrasonic probe 43 to any position on the surface of the to-be-tested battery 5 to detect internal damage, lithium precipitation and state of charge. In the embodiment, a transmission ultrasonic scanning imager is adopted as the ultrasonic scanning imaging module 8, according to the principle, the transmitting probe 47 transmits ultrasonic waves, the ultrasonic waves enter a workpiece, and since the propagation characteristic of the ultrasonic waves in the workpiece is closely related to defects and materials in the workpiece, after the ultrasonic waves are received by the receiving probe 48, an internal defect image of a tested piece can be formed by analyzing, processing and displaying the internal defect image on a screen.

According to the embodiment, the optical imaging module 6, the infrared thermal imaging module 7 and the ultrasonic scanning imaging module 8 are integrated in the semi-closed temperature control box 4, so that the interface stripping and defect nucleation microscopic damage failure mechanism of the to-be-tested battery 5 can be obtained, and synchronous-co-located real-time in-situ monitoring of micro-area microstructure-global temperature gradient when the to-be-tested battery 5 is charged, discharged and loaded and local structure damage real-time in-situ detection during charging and discharging can be realized.

According to the embodiment, the pressing plate 19 and the second pricking needle 20 can be replaced with each other, the pressing plate 19 can realize the extrusion test on the to-be-tested battery 5, and the opposite-vertex pricking can simulate short-circuit damage in the to-be-tested battery 5 and reduce the battery stress release during a single pricking needle pricking test, so that more extreme test loading is created; the environment module 2 creates the local low-temperature environment for the to-be-tested battery 5 and monitors the environment, and the temperature control box 4 can create a constant-temperature environment for the battery; and the charging and discharging module 1 is full-automatic programmable lithium ion battery charging and discharging equipment, can perform over-charge, over-discharge and cyclic charge-discharge tests on the battery, and can perform charging and discharging when the battery cell is subjected to external loading to provide dynamic conditions for performance tests of the battery.

According to the embodiment, the optical imaging module 6 and the infrared thermal imaging module 7 can observe surface damage and deformation, temperature distribution and distortion points of the to-be-tested battery 5 in real time when the mechanical loading module 3 and the charging and discharging module 1 work; the optical imaging module 6, the infrared thermal imaging module 7 and the ultrasonic scanning imaging module 8 can detect the internal damage of the to-be-tested battery 5 in real time when the charging and discharging module 1 works, and can detect the internal damage of the to-be-tested battery 5 after the loading work of the mechanical loading module 3 is finished.

In the testing process, the direct-current servo motor of the loading driving mechanism drives the second pricking needle 20 or the pressing plate 19, and the photoelectric encoder 49 can convert mechanical geometric displacement of the output shaft of the direct-current servo motor into pulse or digital quantity and transmit the pulse or digital quantity to a controller of the direct-current servo motor to achieve alternating load and large-range speed extrusion and pricking. In the loading period, the full-automatic programmable charging and discharging module 1 can perform charging and discharging tests on the to-be-tested battery 5, at the same time, the optical imaging module 6 and the infrared thermal imaging module 7 can perform real-time observation on the loaded to-be-tested battery 5 which is charged and discharged in a low-temperature environment, and the ultrasonic transmitting probe 47 and the ultrasonic receiving probe 48 of the ultrasonic scanning imaging module 8 leave the surface of the to-be-tested battery 5 when the second pricking needle 20 or the pressing plate 19 is loaded, and return to the surface of the to-be-tested battery 5 after mechanical loading is finished to collect the internal damage and crystallographic information of the to-be-tested battery 5. In addition, the mechanical loading module 3 and the charging and discharging module 1 can work independently to achieve loading and monitoring of a single load.

All loading modes and in-situ monitoring modes capable of being achieved in the embodiment are as follows:

over-charge loading-optical-infrared-ultrasonic in-situ monitoring, over-discharge loading-optical-infrared-ultrasonic in-situ monitoring, cyclic charge-discharge loading-optical-infrared-ultrasonic in-situ monitoring, extrusion loading-optical-infrared in-situ monitoring, opposite-vertex pricking loading-optical-infrared in-situ monitoring, alternating cyclic extrusion loading-optical-infrared in-situ monitoring, alternating cyclic opposite-vertex pricking loading-optical-infrared in-situ monitoring, charge-extrusion loading-optical-infrared in-situ monitoring, discharge-extrusion loading-optical-infrared in-situ monitoring, charge-opposite-vertex pricking-loading-optical-infrared in-situ monitoring, discharge-opposite-vertex pricking loading-optical-infrared in-situ monitoring, cyclic charge-discharge-extrusion loading-optical-infrared in-situ monitoring, cyclic charge-discharge-opposite-vertex pricking loading-optical-infrared in-situ monitoring.

The battery in-situ test system 100 can simulate the actual working condition of the to-be-tested battery 5 in a cold environment, and can also perform in-situ monitoring on the force-low temperature-electrochemical coupling microscopic failure mechanism of the to-be-tested battery 5. The mechanical loading module 3 can apply extrusion, opposite-vertex pricking and alternating load to the to-be-tested battery 5; and the optical imaging module 6, the infrared thermal imaging module 7 and the ultrasonic scanning imaging module 8 are integrated in the temperature control box 4, so that real-time observation of the microstructure and temperature distribution of the to-be-tested battery 5 and quantitative analysis of internal defect-crystallographic information can be realized. The embodiment provides instrument support for revealing the performance degradation mechanism and the service life change rule of the battery under the force-low temperature-electrochemical coupling multiple external fields.

Several examples are used for illustration of the principles and implementation methods of the present disclosure. The description of the embodiments is used to help illustrate the method and the core principles of the present disclosure; and meanwhile, those skilled in the art can make various modifications in terms of specific embodiments and scope of application in accordance with the teachings of the present disclosure. In conclusion, the content of this specification shall not be construed as a limitation to the present disclosure.

What is claimed is:

1. A battery in-situ test system, comprising a charging and discharging module, an environment module and a mechanical loading module, wherein a to-be-tested battery is electrically connected with the charging and discharging module, the environment module comprises a temperature control box, the to-be-tested battery, an optical imaging module, an infrared thermal imaging module and an ultrasonic scanning imaging module are arranged in the temperature control box, and the mechanical loading module is used for loading the to-be-tested battery.

2. The battery in-situ test system according to claim 1, wherein the mechanical loading module comprises a loading driving mechanism, a clamp and a first pricking needle, the clamp is located in the environment module and used for clamping the to-be-tested battery, the first pricking needle is arranged below the to-be-tested battery, a pricking needle extruding structure is arranged above the to-be-tested battery, and the loading driving mechanism drives the pricking needle extruding structure to do linear movement.

3. The battery in-situ test system according to claim 2, wherein the battery in-situ test system further comprises a rack, the rack comprises a plurality of stand columns and a cross beam, the loading driving mechanism drives the cross beam to slide along the stand columns, the environment module is fixed to a workbench of the rack, the pricking needle extruding structure comprises a connecting flange and a guide rod, the connecting flange is arranged on the cross beam, a pressure sensor is arranged between the connecting flange and the guide rod, and the lower end of the guide rod is detachably connected with a pressing plate or a second pricking needle.

4. The battery in-situ test system according to claim 2, wherein the clamp is arranged on a vibration isolation table, the first pricking needle penetrates through a through groove in the vibration isolation table, and the center line of the pricking needle extruding structure coincides with the center line of the first pricking needle.

5. The battery in-situ test system according to claim 2, wherein the environment module further comprises a temperature control structure, the temperature control structure comprises a plurality of refrigeration structures and a plurality of temperature sensors, the refrigeration structures are arranged on the outer side of the clamp, and the temperature sensors are arranged on the inner wall of the clamp, the inner walls of the refrigeration structures, the surface of the to-be-tested battery and electrodes of the to-be-tested battery.

6. The battery in-situ test system according to claim 5, wherein each refrigeration structure comprises a cooling fin and a plurality of refrigeration sheets, the cooling fins are arranged on the outer side of the clamp, the refrigeration sheets are arranged between the clamp and the cooling fins, and the sizes of the refrigeration sheets in each refrigeration structure are gradually increased from the clamp to the cooling fins.

7. The battery in-situ test system according to claim 1, wherein the optical imaging module comprises a first bottom plate, a first driving mechanism, a first support and an optical lens, the first bottom plate is fixed to the inner wall of the temperature control box, the first driving mechanism is fixed to the first bottom plate, the first driving mechanism drives the first support to be slidably connected with the first bottom plate, and the optical lens can be slidably connected with the first support and locked with the first support through a hand wheel.

8. The battery in-situ test system according to claim 1, wherein the infrared thermal imaging module comprises a second bottom plate, a second driving mechanism, a third driving mechanism, a transmission mechanism and an infrared lens, the second bottom plate is fixed to the inner wall of the temperature control box, the second driving mechanism drives the infrared lens to rotate, the third driving mechanism drives a second support to rotate through the transmission mechanism, and the infrared lens is rotationally connected with the second support.

9. The battery in-situ test system according to claim 8, wherein the transmission mechanism comprises a first connecting block, a first connecting rod, a second connecting block and a second connecting rod which are hinged in sequence, the first connecting block, the first connecting rod, the second connecting block and the second connecting rod form a parallelogram structure, the first connecting block is in transmission connection with the power output end of the third driving mechanism, and the second connecting block is in transmission connection with the second support.

10. The battery in-situ test system according to claim 1, wherein the ultrasonic scanning imaging module comprises a three-axis movement mechanism and an ultrasonic probe, the three-axis movement mechanism comprises an X-direction movement mechanism, a Y-direction movement mechanism and a Z-direction movement mechanism, the Y-direction movement mechanism is respectively slidably connected with the X-direction movement mechanism and the Z-direction movement mechanism, the ultrasonic probe is arranged on the Z-direction movement mechanism, the ultrasonic probe comprises a transmitting probe and a receiving probe, and when the ultrasonic scanning imaging module works, the transmitting probe and the receiving probe are located on the two sides of the to-be-tested battery.
